(19) United States
(12) Patent Application Publication
(10) Pub. No.: US 2026/0160613 A1
(43) Pub. Date: Jun. 11, 2026

(54) CONTACTLESS PHOTOACOUSTIC TEMPERATURE SENSORS FOR DEVICE MANUFACTURING CHAMBERS

(71) Applicant: Applied Materials, Inc., Santa Clara, CA (US)

(72) Inventors: Usman Chowdhury, Santa Clara, CA (US); Chuang Chia Lin, San Ramon, CA (US); Amir H. Bayati, San Jose, CA (US)

(21) Appl. No.: 18/970,880

(22) Filed: Dec. 5, 2024

(51) Int. Cl. G01K 11/24; H01L 21/67

(52) U.S. Cl. CPC G01K 11/24; H10P 72/0602; H10P 72/0606

(57) ABSTRACT

Disclosed are systems and techniques of contactless temperature measurements in device manufacturing systems using photoacoustic sensors. The techniques include directing a beam of light to a first location of a target object within a chamber of a device manufacturing system, determining, using an optical sensor, one or more characteristics of a displacement of a surface of the target object at a second location, the displacement caused by propagation of one or more acoustic waves between the first location and the second location, and determining, using the one or more characteristics of the displacement, a temperature of the target object.

### TECHNICAL FIELD

The disclosure pertains to semiconductor manufacturing, including device manufacturing systems and sensors used in device manufacturing systems. At least one embodiment relates to temperature sensors that can be deployed in conjunction with device manufacturing systems.

### BACKGROUND

Modern semiconducting devices, such as processing units, memory devices, light detectors, solar cells, light-emitting semiconductor devices, devices that deploy complementary metal-oxide-semiconductor (CMOS) structures, and the like, are often manufactured on silicon wafers (or other suitable substrates). Manufacturing such devices often involves various deposition techniques, such as chemical vapor deposition (CVD) or physical vapor deposition (PVD), etching, photo-masking, polishing, and/or various other operations, in which atoms of one or more selected types are deposited on a substrate held in low or high vacuum environments that are provided by vacuum chambers.

### BRIEF DESCRIPTION OF THE DRAWINGS

The present disclosure will be understood more fully from the detailed description given below and from the accompanying drawings of various embodiments of the disclosure.

FIG. 1 illustrates a schematic view of an example manufacturing system (e.g., a substrate processing system) that deploys a photoacoustic temperature sensing system for contactless measurements of temperatures of substrates and other target objects, according to at least one embodiment.

FIG. 2 is a schematic depiction of an example photoacoustic temperature sensor that can be used for contactless measurements of temperature of target objects in device manufacturing systems, according to at least one embodiment.

FIGS. 3A-3B illustrate dependence of the amplitude and phase features on a sample temperature of example substrates, according to at least one embodiment.

FIG. 4 illustrates example use of reference amplitude-phase data for contactless measurement of temperature of example target objects, according to at least one embodiment.

FIG. 5 is a flowchart illustrating an example method of performing contactless temperature measurements in device manufacturing systems using photoacoustic sensors, according to at least one embodiment.

The present disclosure will be understood more fully from the detailed description given below and from the accompanying drawings of various embodiments of the disclosure.

### SUMMARY

In one embodiment, disclosed is a method that includes directing a beam of light to a first location of a target object within a chamber of a device manufacturing system, determining, using an optical sensor, one or more characteristics of a displacement of a surface of the target object at a second location, the displacement caused by propagation of one or more acoustic waves between the first location and the second location, and determining, using the one or more characteristics of the displacement, a temperature of the target object.

In another embodiment, disclosed is a temperature sensor system that includes a light source to direct a beam of light to a first location of a target object within a chamber of a device manufacturing system and an optical sensor to determine one or more characteristics of a displacement of a surface of the target object at a second location, the displacement caused by propagation of one or more acoustic waves between the first location and the second location. The temperature sensor system further includes a processing device to determine, using the one or more characteristics of the displacement, a temperature of the target object.

In another embodiment, disclosed is a device manufacturing system that includes a plurality of chambers, which include a transfer chamber and one or more processing chambers. The device manufacturing system further includes a temperature sensor having a light source to direct a beam of light to a first location of a target object within one of the plurality of chambers and an optical sensor to determine one or more characteristics of a displacement of a surface of the target object at a second location, the displacement caused by propagation of one or more acoustic waves between the first location and the second location. The device manufacturing system further includes a processing device to determine, using the one or more characteristics of the one, a temperature of the target object.

### DETAILED DESCRIPTION

Maintaining a proper environment in semiconductor manufacturing chambers is important for the quality of manufacturing yield. For example, a plasma density in a CVD chamber that is too high can result in sample etching that is too deep destroying a sample. On the other hand, a plasma density that is too low can lead to slow processing and/or sub-optimal samples. Various inspection and monitoring techniques are, therefore, deployed to measure and correct departures from optimal chamber conditions. Such techniques deploy light sensors, chemical sensors, voltage sensors, current sensors, pressure sensors, gas flow rate sensors, temperature sensors, and/or any other types of sensors. Knowledge of the temperature of samples (e.g., wafers, substrates, and/or the like) located in processing chambers or being transported to/from processing chambers is important for adherence to manufacturing specifications. Incorrect temperature can result in the speed of deposition or etching that is too low or too high and lead to suboptimal or defective products. Temperature sensors that operate by contacting samples can damage the samples or cause impurities to be deposited on the samples. Contactless sensors are less likely to detrimentally affect sample quality but can have low accuracy. A contactless sensor can measure thermal (black body) radiation emitted from the surface of a sample for certain wavelengths of radiation and determine the sample's temperature by fitting the measured intensity to Planck's distribution. Such measurement techniques, however, are limited in their precision by the presence of stray thermal radiation coming from other parts and components of the processing chambers including but not limited to chucks, edge rings, showerheads, pedestal heaters, chamber walls, and/or the like, which can have temperatures that are different from temperature of the sample(s).

Aspects and embodiments of the present disclosure address these and other challenges of the modern device manufacturing technology by providing for temperature sensors that measure temperature of samples and various other target object without direct contact with the target objects in a way that is not influenced by other objects in the environment. More specifically, a light source can direct one or more light pulses or a continuous light to a spot on the sample to induce elastic (acoustic) waves propagating away from the illuminated spot, e.g., along various directions within the sample. A detector, e.g., a laser Doppler vibrometer or some other optical sensor can detect vibrations of the surface of the sample at a detection point of the sample located some distance away from the spot.

The detector can convert oscillations of the surface h(t) of the sample into a complex electrical signal (e.g., characterized by both amplitude and phase). This detected electrical signal can be compared to a reference signal for the light source, e.g., a copy of a signal that drives (turns on/off, modulates, etc.) the light source. For example, the comparison of the two signals can be performed using a lock-in amplifier or a similar device that determines an amplitude a(t) of the detected signal and its phase difference φ(t) with the reference signal, both quantities being functions of time t. A processing device can then extract suitable amplitude A and phase ψ features from the functions a(t) and φ(t), e.g., the maximum amplitude A=max {a(t)} caused by arrival of the elastic wave and a phase difference ψ=φ_{before}−φ_{after}, of the detected signal before and after the arrival of the elastic wave (or vice versa), in one embodiment. The amplitude A and phase ψ can then be used to determine the temperature of the sample T. In one example, controlled laboratory measurements of the amplitude A and phase ψ features can be performed for samples of the same type, size, etc., as a function of temperature T and a reference curve, A=A (T), ψ=ψ(T), parameterized by T can be defined in the amplitude-phase space A-ψ of the signal.

Subsequently, a measurement can be performed on a new sample (e.g., for the same arrangement of the illumination spot and the detection spot), and feature values e.g., Aⱼ and ψⱼ can be extracted for the sample (with index j enumerating the samples). The stored reference curve (and/or other similar reference data) can be used to determine the sample's temperature T based on the measured values Aⱼ and ψⱼ. In one example, the shortest distance from the point (Aⱼ, ψⱼ) to the line A=A(T), ψ=ψ(T) in the amplitude-phase space can be determined, e.g., using a suitably chosen metric for that space, e.g.,

$${D}_{j} ( T ) = {{w}_{A} ( A ( T ) - {A}_{j} )}^{2} + {{w}_{ψ} ( ψ ( T ) - {ψ}_{j} )}^{2} ,$$

with empirically selected amplitude weight w_{A} and phase weight w_{ψ} that are indicative of the relative accuracy given to the amplitude and phase measurements. The temperature of the sample can then be determined by determining a value T for which the distance Dⱼ(T) has a minimum.

Various other embodiments are disclosed herein. For example, a time of acoustic signal propagation (time-of-flight or ToF) can be used as an additional dimension in the amplitude-phase-ToF space A-ψ-t. ToF of the acoustic signal depends on the elastic properties of the sample material (e.g., Young modulus, Poisson ratio, etc.), which in turn depend on temperature. The advantages of the disclosed techniques include but are not limited to fast temperature measurements that, on one hand, do not involve mechanical contacts with samples while, on the other hand, have a high degree of selectivity and obtain temperature measurements of targeted objects not influenced by conditions of other bodies in the same environment. The disclosed embodiments are also capable of facilitating continuous temperature monitoring during performance of processing operations.

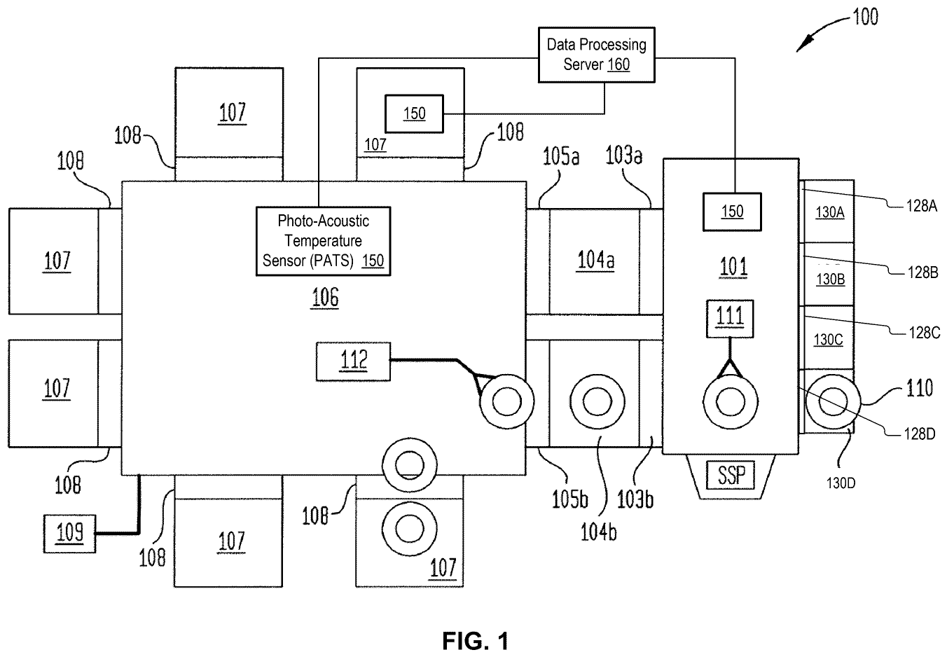

FIG. 1 illustrates a schematic view of an example manufacturing system 100 (e.g., a substrate processing system) that deploys a photoacoustic temperature sensing system for contactless measurements of temperatures of substrates and other target objects, in accordance with some embodiments of the present disclosure. The manufacturing system 100 includes a factory interface (FI) 101 and load ports 128x (e.g., load ports 128A-D). In some embodiments, the load ports 128A-D are directly mounted to (e.g., sealed against) FI 101. Enclosure systems 130x (e.g., cassette, FOUP, process kit enclosure system, or the like) are configured to removably couple (e.g., dock) to the load ports 128A-D. Referring to FIG. 1, enclosure system 130A is coupled to load port 128A, enclosure system 130B is coupled to load port 128B, enclosure system 130C is coupled to load port 128C, and enclosure system 130D is coupled to load port 128D. In some embodiments, one or more enclosure systems 130x are coupled to the load ports 128x for transferring substrates and/or other items into and out of the processing manufacturing system 100. Each of the enclosure systems 130x may seal against a respective load port 128x. In some embodiments, a first enclosure system 130A is docked to a load port 128A. Once such operation or operations are performed, the first enclosure system 130A is undocked from the load port 128A, and then a second enclosure system 130x (e.g., a FOUP containing substrate(s)) is docked to the same load port 128A. In some embodiments, an enclosure system 130x (e.g., enclosure system 130A) is a system for performing a calibration operation or a diagnostic operation.

In some embodiments, a load port 128x includes a front interface that forms an opening. The load port 128x additionally includes a horizontal surface for supporting an enclosure system 130x. Each enclosure system 130x has a front interface that forms a vertical opening. The front interface of the enclosure system 130x is sized to interface with (e.g., seal to) the front interface of the load port 128x (e.g., the vertical opening of the enclosure system 130x is approximately the same size as the vertical opening of the load port 128x). The enclosure system 130x is placed on the horizontal surface of the load port 128x and the vertical opening of the enclosure system 130x aligns with the vertical opening of the load port 128x. The front interface of the enclosure system 130x interconnects with (e.g., clamp to, be secured to, be sealed to) the front interface of the load port 128x. A bottom plate (e.g., base plate) of the enclosure system 130x has features (e.g., load features, such as recesses or receptacles, that engage with load port kinematic pin features, a load port feature for pin clearance, and/or an enclosure system docking tray latch clamping feature) that engage with the horizontal surface of the load port 128x. The same load ports 128x that are used for different types of enclosure systems 130x.

In some embodiments, the manufacturing system 100 also includes first vacuum ports 103a, 103b coupling FI 101 to respective degassing chambers 104a, 104b. Second vacuum ports 105a, 105b are coupled to respective degassing chambers 104a, 104b and disposed between the degassing chambers 104a, 104b and a transfer chamber 106 to facilitate transfer of substrates and other content 110 (e.g., process kit rings) into the transfer chamber 106. In some embodiments, a manufacturing system 100 includes and/or uses one or more degassing chambers 104 and a corresponding number of vacuum ports 103, 105 (e.g., a manufacturing system 100 includes a single degassing chamber 104, a single first vacuum port 103, and a single second vacuum port 105). The transfer chamber 106 includes a plurality of processing chambers 107 (e.g., four processing chambers 107, six processing chambers 107, etc.) disposed therearound and coupled thereto. The processing chambers 107 are coupled to the transfer chamber 106 through respective ports 108, such as slit valves or the like. In some embodiments, FI 101 is at a higher pressure (e.g., atmospheric pressure) and the transfer chamber 106 is at a lower pressure (e.g., vacuum). Each degassing chamber 104 (e.g., load lock, pressure chamber) has a first door (e.g., first vacuum port 103) to seal the degassing chamber 104 from FI 101 and a second door (e.g., second vacuum port 105) to seal the degassing chamber 104 from the transfer chamber 106. Content is to be transferred from FI 101 into a degassing chamber 104 while the first door is open and the second door is closed, the first door is to close, the pressure in the degassing chamber 104 is to be reduced to match the transfer chamber 106, the second door is to open, and the content is to be transferred out of the degassing chamber 104. A local center finding (LCF) device is to be used to align the content in the transfer chamber 106 (e.g., before entering a processing chamber 107, after leaving the processing chamber 107).

In some embodiments, the processing chambers 107 includes or more of etch chambers, deposition chambers (including atomic layer deposition, chemical vapor deposition, physical vapor deposition, or plasma enhanced versions thereof), anneal chambers, or the like.

Factory interface 101 includes a factory interface robot 111. Factory interface robot 111 includes a robot arm, such as a selective compliance assembly robot arm (SCARA) robot. Examples of a SCARA robot include a 2 link SCARA robot, a 3 link SCARA robot, a 4 link SCARA robot, and so on. The factory interface robot 111 includes an end effector on an end of the robot arm. The end effector is configured to pick up and handle specific objects, such as wafers. Alternatively, or additionally, the end effector is configured to handle objects such as a calibration substrate and process kit rings (edge rings). The robot arm has one or more links or members (e.g., wrist member, upper arm member, forearm member, etc.) that are configured to be moved to move the end effector in different orientations and to different locations.

The factory interface robot 111 is configured to transfer objects between enclosure systems 130x (e.g., cassettes, FOUPs) and degassing chambers 104a, 104b (or load ports). The factory interface robot 111 is taught a fixed location relative to a load port 128x using the enclosure system 130x in embodiments. The fixed location in one embodiment corresponds to a center location of an enclosure system 130A placed at a particular load port 128x, which in embodiments also corresponds to a center location of an enclosure system 130B placed at the particular load port 128x. Alternatively, the fixed location may correspond to other fixed locations within the enclosure system 130x, such as a front or back of the enclosure system 130x. The factory interface robot 111 is calibrated using the enclosure system 130x in some embodiments. The factory interface robot 111 is diagnosed using the enclosure system 130x in some embodiments.

Transfer chamber 106 includes a transfer chamber robot 112. Transfer chamber robot 112 includes a robot arm with an end effector at an end of the robot arm. The end effector is configured to handle particular objects, such as wafers. In some embodiments, the transfer chamber robot 112 is a SCARA robot, but may have fewer links and/or fewer degrees of freedom than the factory interface robot 111 in some embodiments.

A controller 109 controls various aspects of the manufacturing system 100. The controller 109 is and/or includes a computing device such as a personal computer, a server computer, a programmable logic controller (PLC), a microcontroller, and so on. The controller 109 includes one or more processing devices, which, in some embodiments, are general-purpose processing devices such as a microprocessor, central processing unit, or the like. More particularly, in some embodiments, the processing device is a complex instruction set computing (CISC) microprocessor, reduced instruction set computing (RISC) microprocessor, very long instruction word (VLIW) microprocessor, or a processor implementing other instruction sets or processors implementing a combination of instruction sets. In some embodiments, the processing device is one or more special-purpose processing devices such as an application specific integrated circuit (ASIC), a field programmable gate array (FPGA), a digital signal processor (DSP), network processor, or the like. In some embodiments, the controller 109 includes a data storage device (e.g., one or more disk drives and/or solid state drives), a main memory, a static memory, a network interface, and/or other components. In some embodiments, the controller 109 executes instructions to perform any one or more of the methods or processes described herein. The instructions are stored on a computer readable storage medium, which include one or more of the main memory, static memory, secondary storage and/or processing device (during execution of the instructions). The controller 109 receives signals from and sends controls to factory interface robot 111 and wafer transfer chamber robot 112 in some embodiments.

According to one aspect of the disclosure, to transfer content 110 (e.g., a substrate or a process kit ring) into a processing chamber 107, the content 110 is removed from a process kit enclosure system 130B via factory interface robot 111 located in FI 101. The factory interface robot 111 transfers the content 110 through one of the first vacuum ports 103a, 103b and into a respective degassing chamber 104a, 104b. A transfer chamber robot 112 located in the transfer chamber 106 removes the content 110 from one of the degassing chambers 104a, 104b through a second vacuum port 105a or 105b. The transfer chamber robot 112 moves the content 110 into the transfer chamber 106, where the content 110 is transferred to a processing chamber 107 through a respective port 108. After processing, the processed content 110 (e.g., a substrate or a used process kit ring) is removed from the manufacturing system 100 in reverse of any manner described herein.

The manufacturing system 100 includes chambers, such as FI 101 (e.g., equipment front-end module, EFEM) and adjacent chambers (e.g., load port 128x, enclosure system 130x, SSP, degassing chamber 104 (such as a loadlock chamber), or the like) that are adjacent to FI 101. Some or all of the chambers can be sealed. In some embodiments, inert gas (e.g., one or more of nitrogen, argon, neon, helium, krypton, or xenon) is provided into one or more of the chambers (e.g., FI 101 and/or adjacent chambers) to provide one or more inert environments. In some examples, FI 101 is an inert EFEM that maintains the inert environment (e.g., inert EFEM minienvironment) within FI 101 so that users do not need to enter FI 101 (e.g., the manufacturing system 100 is configured for no manual access within FI 101).

In some embodiments, gas flow (e.g., inert gas, nitrogen) is provided into one or more chambers (e.g., FI 101) of the manufacturing system 100. In some embodiments, the gas flow is greater than leakage through the one or more chambers to maintain a positive pressure within the one or more chambers. In some embodiments, the inert gas within FI 101 is recirculated. In some embodiments, a portion of the inert gas is exhausted. In some embodiments, the gas flow of non-recirculated gas into FI 101 is greater than the exhausted gas flow and the gas leakage to maintain a positive pressure of inert gas within FI 101. In some embodiments, FI 101 is coupled to one or more valves and/or pumps to provide the gas flow into and out of FI 101. A processing device (e.g., of controller 109) controls the gas flow into and out of FI 101. In some embodiments, the processing device receives sensor data from one or more sensors (e.g., oxygen sensor, moisture sensor, motion sensor, door actuation sensor, temperature sensor, pressure sensor, etc.) and determines, based on the sensor data, the flow rate of inert gas flowing into and/or out of FI 101.

The enclosure system 130x also allows for training, calibrating, and/or diagnosing a robot arm (e.g., of factory interface robot) without opening the sealed environment within FI 101 and adjacent chambers. The enclosure system 130x seals to the load port 128x responsive to being docked on the load port 128x. The enclosure system 130x provides purge port access so that the interior of the enclosure system 130x can be purged prior to opening the enclosure system 130x to minimize disturbance of the inert environment within FI 101.

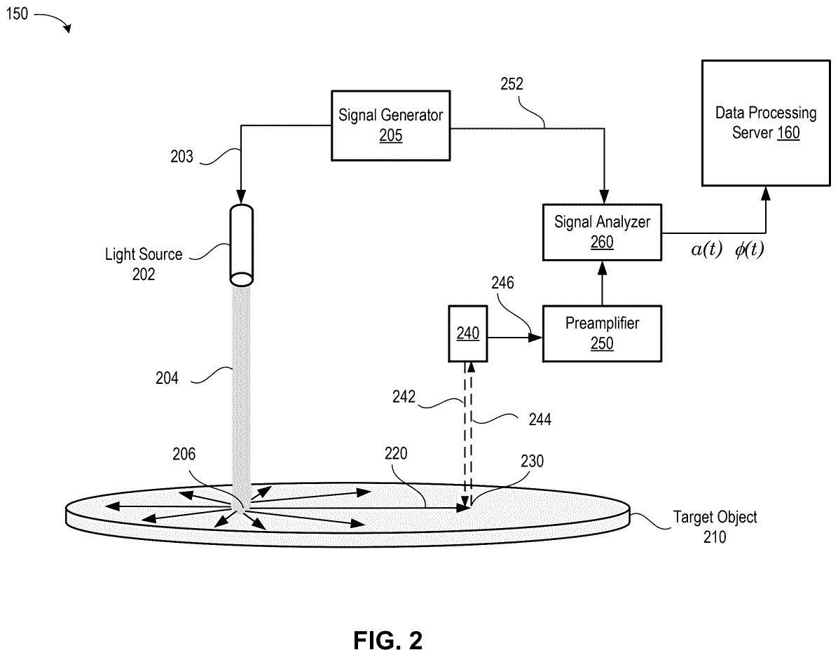

Manufacturing system 100 can deploy one or more photoacoustic temperature sensors (PATS) 150 capable of using a combination of optical sensing and elastic wave propagation to measure temperature of target objects, e.g. substrates, chucks, edge rings, and/or the like, as disclosed in more detail in conjunction with FIGS. 2-4. As illustrated, PATS 150 can be placed in the transfer chamber 106 and used to determine temperature of substrates being transported between processing chambers 107 and/or between processing chambers 107 and degassing chambers 104, e.g., after completion of one manufacturing operation and/or before the start of a next operation. PATS 150 can also be placed in any one (or more) of processing chambers 107 and used to measure temperature of substrates before, during, and/or after one or more manufacturing operations performed in those chambers. In some embodiments, PATS 150 further be placed in one or more degassing chambers 104n or FI 101. In some embodiments, PATS 150 can be permanently or removably mounted in a particular chamber, e.g., one or more processing chambers 107. In some embodiments, PATS 150 can be transported between different chambers by a robot, e.g., factory interface robot 111 or transfer chamber robot 112. In one illustrative example, transfer chamber robot 112 can pick up a PATS 150 located in transfer chamber 106 and move PATS 150 to one of processing chambers 107 via respective port 108. Transfer chamber robot 112 can hover PATS 150 over a substrate in the processing chamber at a certain predetermined location relative to the substrate (including height and lateral coordinates) to perform a temperature measurement for the substrate, before retracting PATS 150 back to transfer chamber 106.

Data collected by PATS 150 can be communicated (e.g., over wired or wireless connection) to data processing server 160, which can include one or more processing devices, e.g., central processing units (CPUs), microcontrollers, ASICs, FPGAs, DSPs, and/or the like. The processing device(s) can include, or communicate with, one or more memory devices capable of storing instructions that control operations of PATS 150, including moving (if applicable) PATS 150 near a target's location, operating a light source and a vibrometer detector, converting an optical vibrometer signal to an electrical signal, comparing the electrical signals to a reference signal, determining amplitude, phase, and/or other signal characteristics, and comparing the signal characteristics with stored reference data to determine the temperature of the substrate (or any other target).

FIG. 2 is a schematic depiction of an example photoacoustic temperature sensor 150 that can be used for contactless measurements of temperature of target objects in device manufacturing systems, according to at least one embodiment. As illustrated, a light source 202 can direct a beam of light 204 to produce an illuminated spot 206 on a target object 210, which can be a sample, e.g., a substrate, a wafer, an edge ring, a chuck, a gas showerhead, a pedestal heater, and/or any other object present in one of the chambers of a manufacturing system, e.g., manufacturing system 100 of FIG. 1.

A “wafer” or “substrate,” as used herein, refers to any material capable of supporting one or more films, masks, photoresists, layers, etc., that are deposited, formed, etched, or otherwise processed during a fabrication process. For example, a wafer surface on which processing can be performed includes materials such as silicon, silicon oxide, silicon nitride, strained silicon, silicon on insulator, carbon doped silicon oxides, amorphous silicon, doped silicon, germanium, gallium arsenide, glass, sapphire, plastic, and any other materials such as metals, metal nitrides, metal alloys, and other conductive materials, depending on the application. Wafers include, without limitation, semiconductor wafers. Wafers may be exposed to a pretreatment process to polish, etch, reduce, oxidize, hydroxylate, anneal, UV cure, e-beam cure and/or bake the substrate surface. In addition to film processing directly on the surface of the wafer itself, any of the film processing steps disclosed may also be performed on an underlayer formed on the wafer as disclosed in more detail below, and the term “wafer surface” is intended to include such underlayer as the context indicates. Thus, for example, where a film/layer or partial film/layer has been deposited onto a wafer surface, the exposed surface of the newly deposited film/layer becomes the wafer surface. In some embodiments, wafers have a thickness in the range of 0.25 mm to 1.5 mm, or in the range of 0.5 mm to 1.25 mm, in the range of 0.75 mm to 1.0 mm, or more. In some embodiments, wafers have a diameter of about 10 cm, 20 cm, 30 cm, or more.

Light source 202 can include any suitable narrowband (e.g., monochromatic) or broadband source of light, including but not limited to a laser, a semiconductor laser, a gas laser, an excimer laser, a laser diode, a light-emitting diode (LED), and/or the like. Light source 202 can be a pulsed light source, a continuous light source, a single-model light source, a multi-mode light source, and/or the like. In embodiments where light source 202 deploys a device that emits a continuous beam, light source 202 can include a suitable continuous beam chopper to create pulses of desired duration and repetition rate and/or a beam modulator to partially modulate the amplitude of the beam of light 204. Light source 202 can be capable of generating the beam of light 204 that is polarized, unpolarized, or partially polarized. Beam of light 204 can be a flood light, a focused light, a collimated light, and/or a light that has undergone any suitable optical beam shaping. In some embodiments, illuminated spot 206 can be circular, elliptic, line-like, or have some other form.

Beam of light 204 can have wavelengths in any suitable range of electromagnetic radiation, e.g., microwave radiation, infrared radiation, optical radiation, near UV radiation, far UV radiation, x-rays, and/or the like. The size of the illuminated spot 206, e.g., diameter d, can be between 1 mm and 10 mm, in some embodiments. In other embodiments, the size of the illuminated spot 206 can be less than 1 mm or more than 10 mm.

Intensity and/or duration of the beam of light 204 can be sufficiently large to cause propagation of one or more acoustic waves (indicated with solid arrows), e.g., acoustic wave 220, causing a detectable deformation (displacement) of the surface of target object 210, but not so large as to cause heating of target object 210 and resulting substantial modification of the target object's temperature. Accordingly, the intensity I and duration Δt of the beam of light 204 can be such that the resulting heating ΔT of the target object 210 (e.g., near the illuminated spot 206) is less than a target accuracy of temperature determination (e.g., 0.5° C., 1° C., 2° C., 5° C., and/or the like). The heating AT can be estimated as ΔT≈IΔt/C(d), where C(d) is the heat capacity of a portion of the target object 210 of the size ˜d³.

Light source 202 can output the beam of light 204 having any suitable intensity profile I(t) as a function of time. The beam of light 204 can be generated responsive to a suitable electrical driving signal 203 produced by a signal generator 205. Driving signal 203 can cause the beam of light 204—a continuous and modulated beam or a sequence of pulses—to have any desired (target) amplitude modulation, frequency modulation, and/or phase modulation.

In some embodiments, the frequency (wavelength) of the beam of light 204 can be selected to ensure that the light is absorbed by the material of the target object 210 and is converted into mechanical energy of elastic waves. For example, photons of the beam of light 204 can excite electron-hole pairs (e.g., having energy that is at least the conduction-valence bandgap) that can subsequently relax non-radiatively, e.g., via emission of phonons (quanta of acoustic waves). As indicated by the solid arrows, acoustic waves can propagate in various directions along the surface of target object 210. Among the propagating waves can be longitudinal acoustic waves, transverse acoustic waves, Rayleigh-Lamb waves, and/or other elastic waves as can be supported by crystal structure of the target object 210 materials. These waves can be accompanied by vibrations h(x, y; t) of the height of the surface of target object 210. (It can be expected that the transverse acoustic waves and Rayleigh-Lamb waves are to cause stronger modulation of the height compared with the longitudinal waves associated with elastic displacement along the direction of the wave propagation).

An optical sensor 240 can detect these vibrations at a detection point 230 on the target sample 210 located at some known distance L from the illuminated spot 206. Distance L can be 5-10 cm, although is some embodiments, distance L can be less than 5 cm (e.g., 3-4 cm, or more than 10 cm (e.g., 11-20 cm).

Optical sensor 240 can be any suitable device capable of measuring distance from some reference height above the target object 210 (e.g., a height of transmitter and/or receiver of optical sensor 240) and a dynamically oscillating surface of target object 210. In some embodiments, optical sensor 240 can be a lidar-type detection device, e.g., a laser Doppler vibrometer, which determines the height (displacement) of the surface h(x₀, y₀; t) at or near detection point 230 (with coordinates x₀, y₀) as a function of time t. In some embodiments, operations of optical sensor 240 can be based on interferometry techniques, optical signal time-of-flight detection, heterodyne detection, and/or the like, or any combination thereof. In some embodiments, optical sensor 240 can operate by transmitting an incident beam 242 towards the target object 210 and detecting a reflected beam 244 returned to the optical sensor 240. Incident beam 242 and reflected beam 244 can use any suitable range of electromagnetic radiation, e.g., microwave radiation, infrared light, optical light, UV light, and/or the like.

Optical sensor 240 can convert, e.g., using any suitable set of photodetectors, oscillations of the surface h(x₀, y₀; t) of the target object 210 into a complex (electrical) detected signal 246 having both amplitude and phase. In some embodiments, complex detected signal 246 can be enhanced by a preamplifier 250. Complex detected signal 246 processed by preamplifier 250 can be used as a first input into a signal analyzer 260. A second input into signal analyzer 260 can be a reference signal 252 representative of the driving signal 203 for the light source 202, e.g., a copy of driving signal 203 or a signal that differs from driving signal 203 by a fixed amplitude factor and/or a fixed phase shift. In some embodiments, signal analyzer 260 can be (or include) a lock-in amplifier.

Signal analyzer 260 can extract an amplitude a(t) of the complex detected signal 246 and its phase @ (t) relative to the reference signal 252, e.g., by computing a product of the complex detected signal 246 and reference signal 252 and integrating (averaging) the computed product over time. Amplitude a(t) and phase φ(t) can be provided to data processing server 160 that can extract, from a(t) and φ(t), suitable amplitude A and phase ψ features.

In one example non-limiting embodiment, the amplitude feature A can be a maximum amplitude A=max {a(t)} caused by the arrival of the acoustic wave 220. The phase feature ψ can be a phase difference ψ=φ_{before}−φ_{after}, of the phase φ_{before} before arrival of the acoustic wave and the phase φ_{after} after the arrival of the acoustic wave or some other phase feature (e.g., a phase difference before the arrival of the wave and at the maximum of the detected deformation caused by the acoustic wave).

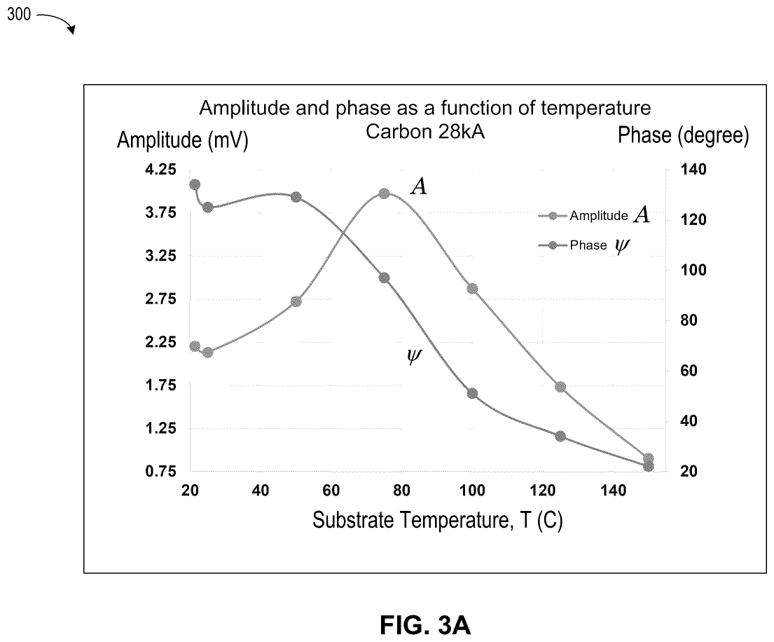

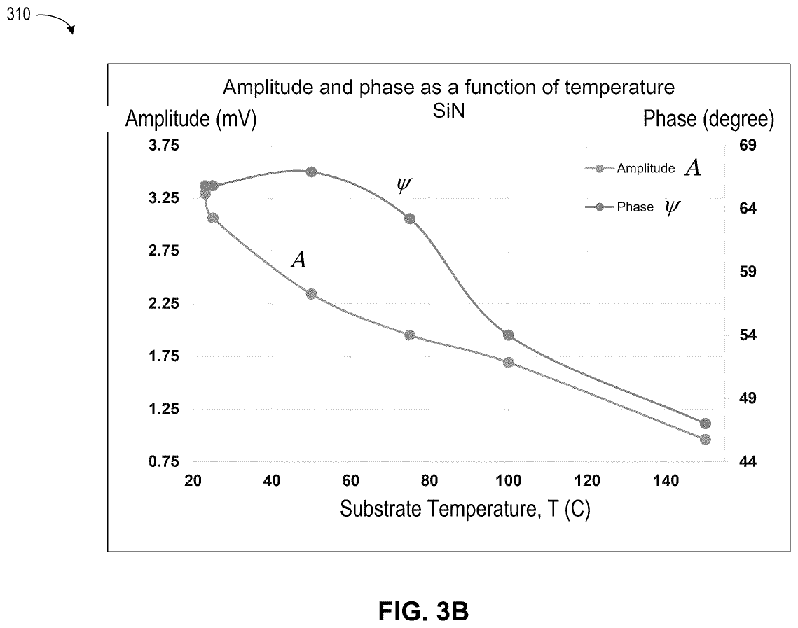

FIGS. 3A-3B illustrate dependence of the amplitude and phase features on a sample temperature of example substrates, according to at least one embodiment. FIG. 3A illustrates dependence 300 of amplitude feature A and phase feature d on temperature for a carbon substrate. FIG. 3B illustrates dependence 310 of amplitude feature A and phase feature ψ on temperature for a silicon nitride substrate. Example dependencies 300 and 310 can be measured for specific target objects and specific reference locations of illuminated spot 206 and detection point 230 and stored as part of reference data A=A(T), ψ=ψ(T).

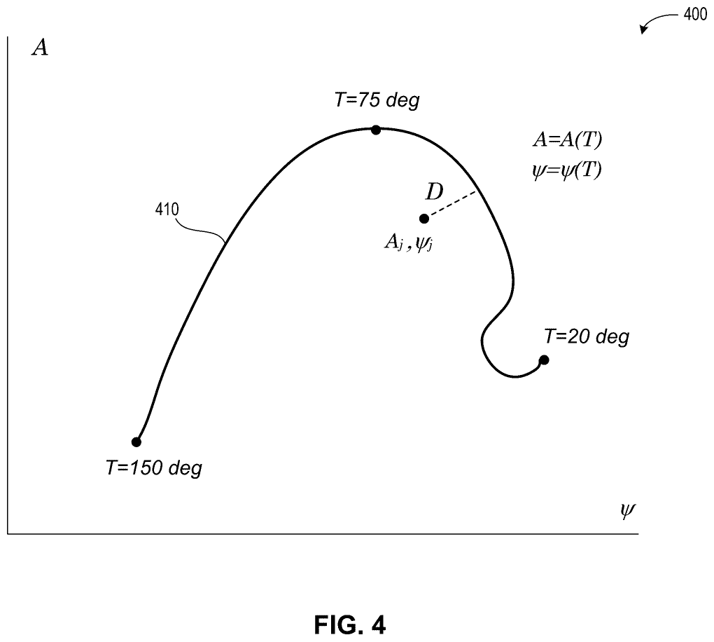

FIG. 4 illustrates example use of reference amplitude-phase data for contactless measurement of temperature of example target objects, according to at least one embodiment. More specifically, FIG. 4 depicts schematically the amplitude-phase space A-ψ400 and an example reference data represented via a reference curve 410 in the amplitude-phase space 400. The reference curve 410 corresponds to the reference data illustrated in FIG. 3A for the carbon substrate. The reference curve 410 is parameterized via the temperature of the sample T:A=A (T), ψ=ψ(T). As temperature increases from T=20° C. to T=150° C., the reference curve 410 is traversed starting from the right end of the curve towards the left end of the curve with the maximum amplitude encountered at about T=75° C.

A measurement on a new substrate can be performed for the same arrangement of the illumination spot and the detection point (e.g., relative to crystallographic directions of the target object) and can determine feature values Aⱼ and ψⱼ (with subscript j enumerating processed substrates, j=1, 2, 3 . . . ). The obtained point (Aⱼ, ψⱼ) can then be mapped to a point (A (T), ψ(T)) that lies on the reference curve 410, e.g., a point on the reference curve 410 that is the closest to the measured point (Aⱼ, ψⱼ) with the temperature T of the closest point taken as the determined temperature of substrate j. In some embodiments, distances in the amplitude-phase space 400 can be defined using a suitably chosen metric, e.g., a set of weights: an amplitude weight w_{A} and a phase weight W_{ψ} that can be set empirically, e.g., via experimentation for a given substrate type, locations of the illumination spot and the detection point, and/or other relevant factors,

$${D}_{j} ( T ) = {{w}_{A} ( A ( T ) - {A}_{j} )}^{2} + {{w}_{ψ} ( ψ ( T ) - {ψ}_{j} )}^{2} .$$

In some embodiments, one of the weights can be set to unity, e.g., W_{A}→1, with the other weight, e.g., W_{ψ}/W_{A}, or simply W_{ψ} indicating relative importance given to phase measurement compared to the amplitude measurements, with small values W_{ψ} indicative of more weigh given to amplitude measurements and larger values W_{ψ} giving more weight to phase measurements.

In some embodiments, in addition to (or instead of) measuring the amplitude and/or phase, PATS 150 can measure the time of flight (ToF) of the acoustic wave, e.g., the time t between a pulse of the beam of light 204 striking target object 210 and the time it takes for the acoustic wave 220 to reach the detection point 230, located some known distance L away. The ratio v=L/τ then represents the speed of acoustic wave propagation (sound velocity). This measured sound velocity can then be compared with the speed of sound known from solution of elastic equations and temperature dependence of elastic moduli Cᵢⱼₖₗ on temperature.

In one example of a cubic crystal, tensor of elastic moduli Cᵢⱼₖₗ can have three non-zero components: Cₓₓₓₓ, C_{xxyy}, and C_{xyxy} (with other components, having the same structure, e.g., C_{xxyy}=C_{zzxx}). Along the direction [100] of the cubic lattice, the longitudinal waves propagate with the velocity of v_{l-[100]}=\sqrt{Cₓₓₓₓ/ρ}, where ρ is the mass density of the crystal, while the transverse waves propagate with the velocity v_{t-[100}]=\sqrt{C_{xyxy}/ρ}. Similarly, for the waves propagating along the [110] direction, the longitudinal sound velocity is v_{l-[110]}=\sqrt{(CₓₓₓₓC_{xxyy}+2C_{xyxy})/ρ} and the two transverse sound velocities are v_{t-[101}]=\sqrt{(Cₓₓₓₓ−C_{xxyy})/2ρ, C_{xyxy}/2ρ}. The waves propagating along the [111] direction include the longitudinal waves propagating with velocity v_{l-[111]}=\sqrt{(Cₓₓₓₓ+2C_{xxyy}+4C_{xyxy})/3ρ} and the transverse sound velocity v_{t-[111]}=\sqrt{(Cₓₓₓₓ−C_{xxyy}+C_{xyxy})/3ρ}. Based on the known (e.g., measured) temperature dependence, the elastic moduli can be approximated as linear functions of the difference of the temperature T and some reference temperature T₀, Cₓₓₓₓ(T)=Cₓₓₓₓ(T₀)+αₓₓₓₓ(T−T₀). As a result, measured velocity of one or more of the sound waves can be related to the elastic moduli, which can in turn be related to the change in temperature T−T₀. For circular target objects, e.g., substrates, the direction of the acoustic wave propagation relative to crystallographic direction of the crystal, e.g., [100], [010], [110], [111], etc., can be known based on a reference feature (e.g., notch, cut, etc.) of substrate. The reference feature can be detected using various aligner techniques (e.g., by spinning the substrate until the notch is found) prior to the substrate being transported into one of the chambers for processing.

Propagation of acoustic waves with velocities v that are independent of the wavelength/(with dispersion v(λ)=v/λ, where v is the frequency of the wave) occurs if the wavelength is less than the thickness d of the sample, λ<<d. Typical wavelengths λ are of the order of the size of the illuminated spot 206. In the opposite limit of long wavelengths λ>>d, the dispersion of the longitudinal waves does not change, but the transverse waves become flexural (bending) in waves plates whose dispersion is quadratic, v(λ)˜(d/λ²)\sqrt{C/ρ}, and whose velocity becomes small as large wavelength increases.

In some embodiments, ToF measurements can be performed independently of the amplitude measurements. In some embodiments, ToF measurements can be used in conjunction with the amplitude-phase measurements. For example, the amplitude-phase space A-ψ can be augmented with the third, ToF, dimension into the amplitude-phase-ToF space A-ψ-τ, with reference (calibration) data also including measurements of ToF as a function of temperature τ(T). In such instances, temperature T can be obtained by determining a point of the reference curve A=A(T), ψ=ψ(T), t=t(T) having the shortest distance (computed using a suitable three-dimensional distance metric with an additional weight given to ToF values) to the measurement point (Aⱼ, ψⱼ, τⱼ), in a way that is similar to the computations described in conjunction with FIG. 4.

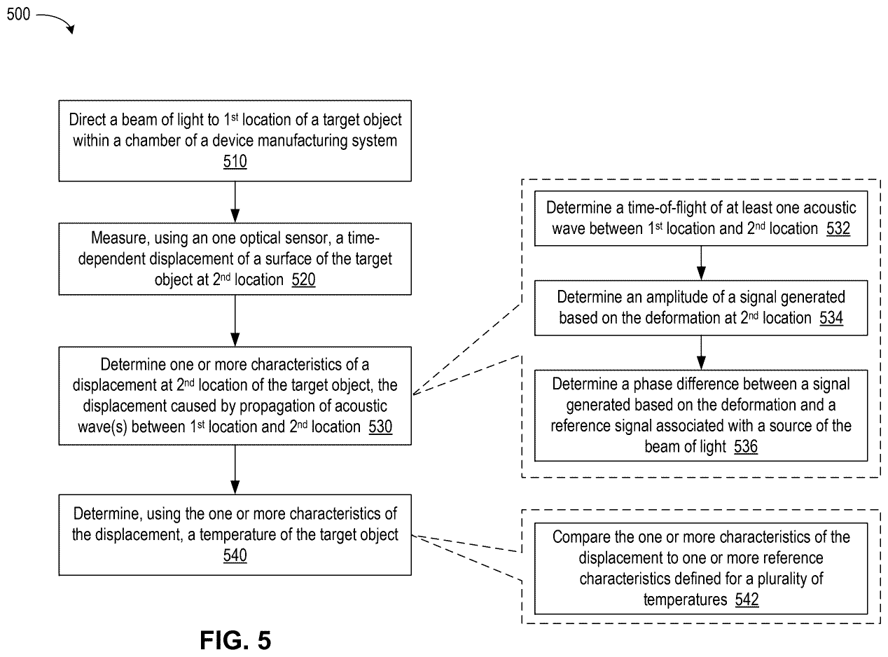

FIG. 5 is a flowchart illustrating an example method 500 of performing contactless temperature measurements in device manufacturing systems using photoacoustic sensors, according to at least one embodiment. Although various operations of method 500 are depicted using a particular sequence of operations (flowchart blocks), in various embodiments, operations of method 500 can be performed in other suitable orders. In some embodiments, some operations of method 500 can be performed concurrently with other operations.

At block 510, method 500 can include directing a beam of light (e.g., beam of light 204 in FIG. 2) to a first location (e.g., illuminated spot 206 in FIG. 2) of a target object (e.g., target object 210 in FIG. 2) within a chamber of a device manufacturing system (e.g., manufacturing system 100 in FIG. 1). In some embodiments, the target object can include a substrate, a toolkit, a gas showerhead, a chuck, a pedestal heater, and/or the like. In some embodiments, the chamber can include at least one of a deposition chamber, an etch chamber, a transfer chamber, a degassing chamber, a front-end interface chamber, and/or the like.

At block 520, method 500 can include using an optical sensor (e.g., optical sensor 240 in FIG. 2) to measure a time-dependent displacement of a surface of the target object at the second location (e.g., detection point 230 in FIG. 2). In some embodiments, the optical sensor can include a laser-based (e.g., Doppler) vibrometer. In some embodiments, the first location and the second location are at least 5 cm apart.

At block 530, method 500 can continue with determining one or more characteristics of the displacement of the surface of the target object at the second location. The displacement can be caused by a propagation of one or more acoustic waves (e.g., transverse waves, longitudinal waves, Rayleigh-Lamb waves, etc.) between the first location and the second location. In some embodiments, determining the one or more characteristics of the displacement of the surface can include operations illustrated with the top callout portion of FIG. 5. More specifically, at block 532, method 500 can include determining a time of flight of at least one acoustic wave (e.g., a longitudinal wave, a transverse wave, a Rayleigh-Lamb wave, and/or the like) of the one or more acoustic waves between the first location and the second location. At block 534, method 500 can include determining an amplitude of a signal generated based on the displacement. At block 536, method 500 can include determining a phase difference between a signal generated based on the displacement and a reference signal associated with a source of the beam of light.

At block 540, method 500 can continue with determining, using the one or more characteristics of the displacement, a temperature of the target object. In some embodiments, determining the temperature of the target object can include operations illustrated with the bottom callout portion of FIG. 5. More specifically, at block 542, method 500 can include comparing the one or more characteristics of the displacement (e.g., amplitude features, phase features, time of flight, and/or the like) to one or more reference characteristics defined for a plurality of temperatures (e.g., reference curve 410 in FIG. 4).

It is to be understood that the above description is intended to be illustrative, and not restrictive. Many other embodiment examples will be apparent to those of skill in the art upon reading and understanding the above description. Although the present disclosure describes specific examples, it will be recognized that the systems and methods of the present disclosure are not limited to the examples described herein, but can be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

What is claimed is:

1. A method comprising:
directing a beam of light to a first location of a target object within a chamber of a device manufacturing system;
determining, using an optical sensor, one or more characteristics of a displacement of a surface of the target object at a second location, the displacement caused by propagation of one or more acoustic waves between the first location and the second location; and
determining, using the one or more characteristics of the displacement, a temperature of the target object.

2. The method of claim 1, wherein the target object comprises at least one of a substrate, a toolkit, a gas showerhead, or a chuck.

3. The method of claim 1, wherein the chamber comprises at least one of a deposition chamber, an etch chamber, a transfer chamber, a degassing chamber, or a front-end interface chamber.

4. The method of claim 1, wherein the optical sensor comprises a laser-based vibrometer.

5. The method of claim 1, wherein the first location and the second location are at least 5 cm apart.

6. The method of claim 1, wherein determining the one or more characteristics of the displacement of the surface of the target object at the second location comprises:
determining a time of flight of at least one acoustic wave of the one or more acoustic waves between the first location and the second location.

7. The method of claim 1, wherein determining the one or more characteristics of the displacement of the surface of the target object at the second location comprises:
determining an amplitude of a signal generated based on the displacement.

8. The method of claim 1, wherein determining the one or more characteristics of the displacement of the surface of the target object at the second location comprises:
determining a phase difference between a signal generated based on the displacement and a reference signal associated with a source of the beam of light.

9. The method of claim 1, wherein determining the temperature of the target object comprises:
comparing the one or more characteristics of the displacement to one or more reference characteristics defined for a plurality of temperatures.

10. The method of claim 1, wherein the one or more acoustic waves are induced by interaction of the first beam of light with the target object at the first location.

11. A temperature sensor system, comprising:
a light source to direct a beam of light to a first location of a target object within a chamber of a device manufacturing system;
an optical sensor to determine one or more characteristics of a displacement of a surface of the target object at a second location, the displacement caused by propagation of one or more acoustic waves between the first location and the second location; and
a processing device to determine, using the one or more characteristics of the displacement, a temperature of the target object.

12. The temperature sensor system of claim 11, wherein the target object comprises at least one of a substrate, a toolkit, a gas showerhead, or a chuck.

13. The temperature sensor system of claim 11, wherein the chamber comprises at least one of a deposition chamber, an etch chamber, a transfer chamber, a degassing chamber, or a front-end interface chamber.

14. The temperature sensor system of claim 11, wherein the optical sensor comprises a laser Doppler vibrometer.

15. The temperature sensor system of claim 11, wherein the first location and the second location are at least 5 cm apart.

16. The temperature sensor system of claim 11, wherein the one or more characteristics of the displacement of the surface of the target object at the second location comprise a time of flight of at least one acoustic wave of the one or more acoustic waves between the first location and the second location.

17. The temperature sensor system of claim 11, wherein the one or more characteristics of the displacement of the surface of the target object at the second location comprise an amplitude of a signal generated based on the displacement.

18. The temperature sensor system of claim 11, wherein the one or more characteristics of the displacement of the surface of the target object at the second location comprise a phase difference between a signal generated based on the displacement and a reference signal associated with a source of the beam of light.

19. The temperature sensor system of claim 11, wherein to determine the temperature of the target object, the processing device is to compare the one or more characteristics of the displacement to one or more reference characteristics defined for a plurality of temperatures.

20. A device manufacturing system, comprising:
a plurality of chambers, comprising:
a transfer chamber; and
one or more processing chambers;
a temperature sensor, comprising:
a light source to direct a beam of light to a first location of a target object within one of the plurality of chambers;
an optical sensor to determine one or more characteristics of a displacement of a surface of the target object at a second location, the displacement caused by propagation of one or more acoustic waves between the first location and the second location; and
a processing device to determine, using the one or more characteristics of the one, a temperature of the target object.

21. The device manufacturing system of claim 20, wherein the optical sensor comprises a laser Doppler vibrometer to generate an electrical signal representative of the displacement of the surface of the target object at the second location, and wherein to determine the temperature of the target object, the processing device is to determine at least one of:
a time of flight of at least one acoustic wave of the one or more acoustic waves between the first location and the second location,
an amplitude of the electrical signal, or
a phase difference between the electrical signal and a reference signal associated with the light source.
